(19) United States
(12) Patent Application Publication
(10) Pub. No.: US 2020/0350233 A1
(43) Pub. Date: Nov. 5, 2020

(54) Microjet-Cooled Flanges for Electronic Devices

(71) Applicant: Jetcool Technologies, Inc., Littleton, MA (US)

(72) Inventors: Jordan Mizerak, Boston, MA (US); Bernard Malouin, Westford, MA (US)

(21) Appl. No.: 15/931,284

(22) Filed: May 13, 2020

Related U.S. Application Data
(63) Continuation of application No. PCT/US20/27599, filed on Apr. 10, 2020.
(60) Provisional application No. 62/831,888, filed on Apr. 10, 2019.

(51) Int. Cl. H01L 23/473; H01L 23/13

(52) U.S. Cl. CPC H01L 23/4735; H01L 23/13

(57) ABSTRACT

An electronic component flange with integral microjet cooling for thermal management of the component. Electronic components are commonly packaged with a base material, base plate, or flange. These flanges also conduct heat away from the heat-generating electronic component. Microjet-cooled flanges build high performance microjet cooling into this component base plate, or flange, providing effective cooling without the coolant fluid contacting the electronic device/itself. This technology serves as a replacement for traditional electronics flanges, notably for devices with high power dissipations or a need for lower temperatures. This technology enables higher power electronic components, without a need for direct contact with the coolant fluid. Moreover, many applications may benefit from the ability to include microjet-cooled flanges into the existing flange or package geometries, for easier adoption into existing assembly processes.

### CROSS-REFERENCE TO RELATED APPLICATION

This application claims priority of PCT/US20/27599, filed on Apr. 10, 2020, which claimed priority of Provisional Patent Application 62/831,888, filed on Apr. 10, 2019. The entire disclosures of both applications are incorporated herein by reference for all purposes.

### BACKGROUND

This disclosure relates to an internally-cooled flange for mounting electronic devices.

Many of today's electronic devices are in search of greater performance, but in smaller package sizes. This increases the power-density of the devices, which can be challenging for thermal management systems. For example, power amplifiers for defense, radar, and telecom look to increase the power levels of devices while reducing the sizes of packages. Insulated-gate bipolar transistors (IGBTs) for electric vehicles seek to increase the amperage rating of devices, while maintaining reliable device temperatures. Laser diodes for defense, communications, and industrial equipment can increase optical power, but may then experience undesirable wavelength shifts due to temperature variations. In these examples, and others, the thermal management challenges created by increasing power-density require the introduction of higher performance thermal management approaches, and ones that also come in small packages.

Current approaches to cooling these types of devices involve the attachment of the device to a conductive metal flange. This flange typically forms part of the final component's package. Heat is conductively transferred from the device to the flange, where it is spread out and then dissipated to a system-level heat sink. These strategies have historically been effective but are reaching their performance limits for high power-density devices. Further, these solutions require large, heavy, and expensive system-level metal heat sinks to help dissipate the heat from the flange. Increasing the size of these heat sinks is incompatible with the desired miniaturization of modern electronics.

Advanced approaches to cooling high power devices include modification to the actual electronic device, for example by etching microchannels into the chip or substrate. These approaches are very effective and can be built into small package sizes. However, such invasive approaches may not be compatible with existing assembly processes and must typically be considered during initial device design and fabrication.

### SUMMARY

It would, therefore, be useful to have an electronics flange that includes high performance cooling features to: eliminate the need for additional metal heat sinks; produce better cooling to accommodate higher power devices; remain compatible with existing flange assembly architectures; and require no modification or fluid-contact to the electronic device itself.

All examples and features mentioned below can be combined in any technically possible way.

In one aspect a flange for cooling an electronic component includes a heat transfer portion with an inner surface, and an opposed outer surface that is configured to be thermally coupled to the electronic component, a high-pressure fluid reservoir, a fluid inlet in fluid communication with the high-pressure reservoir, the inlet configured to conduct single-phase cooling fluid into the flange, a low-pressure fluid reservoir that is in fluid communication with the inner surface of the heat transfer portion, a fluid outlet in fluid communication with the low-pressure reservoir, the outlet configured to conduct the fluid out of the flange, and a plurality of fluid nozzles that are each configured to transmit the fluid from the high pressure reservoir to the low pressure reservoir in the form of jets that are configured to strike the inner surface of the heat transfer portion.

Some examples include one of the above and/or below features, or any combination thereof. In an example a perimeter can be drawn around the plurality of fluid nozzles without encompassing the fluid outlet. In an example the fluid nozzles are configured non-uniformly relative to the heat transfer portion, to provide more effective cooling to certain areas for reduction of temperature gradients across the electronic component. In some examples the flange is of unitary structure. In an example the flange is fabricated using additive manufacturing. In some examples the plurality of fluid nozzles form microjet nozzles. In an example the microjet nozzles serve to form jets that are configured to strike substantially perpendicularly to the inner surface of the heat transfer portion, to create fluid flow with substantially high momentum in said perpendicular direction. In an example the flange is configured to serve as an electronics base plate.

Some examples include one of the above and/or below features, or any combination thereof. In some examples the flange is fabricated from at least two distinct members that are joined together. In an example a first member comprises the heat transfer portion that is made from a material with high heat conductivity. In an example a second member is made from a material with lower heat conductivity than that of the first member. In an example the flange further includes at least one hole or slot that is configured to attach the flange to another structure. In an example the heat transfer portion is configured to provide a short, direct path from a primary thermal interface of the electronics component to the inner surface of the heat transfer portion. In an example the fluid nozzles comprise orifices through a thickness of an internal microjet nozzle plate of the flange. In an example the electronic component comprises at least one transistor. In an example the electronic component comprises at least one laser diode.

In another aspect a flange that is configured to serve as a base plate for and to cool an electronic component includes a heat transfer portion with an inner surface, and an opposed outer surface that is configured to be thermally coupled to the electronic component, wherein the heat transfer portion is configured to provide a short, direct path from a primary thermal interface of the electronics component to the inner surface of the heat transfer portion, a high-pressure fluid reservoir, a fluid inlet in fluid communication with the high-pressure reservoir, the inlet configured to conduct single-phase cooling fluid into the flange, a low-pressure fluid reservoir that is in fluid communication with the inner surface of the heat transfer portion, a fluid outlet in fluid communication with the low-pressure reservoir, the outlet configured to conduct the fluid out of the flange, and a plurality of fluid microjet nozzles that are each configured to transmit the fluid from the high pressure reservoir to the low pressure reservoir in the form of jets that are configured to strike the inner surface of the heat transfer portion.

Some examples include one of the above and/or below features, or any combination thereof. In some examples the flange is fabricated from at least two distinct members that are bonded together, wherein a first member comprises the heat transfer portion that is made from a material with high heat conductivity. In an example a second member is made from a material with lower heat conductivity than that of the first member. In an example the fluid microjet nozzles comprises orifices through a thickness of an internal microjet nozzle plate of the flange.

### BRIEF DESCRIPTION OF THE DRAWINGS

For a better understanding of the present disclosure, reference is made to the accompanying drawings, in which:

FIG. 1 shows a cross sectional view of one embodiment of a microjet-cooled flange for electronic devices.

FIG. 2 shows a cross sectional view of one embodiment of a microjet-cooled flange with multi-layer construction.

FIG. 3 shows an isometric view of one embodiment of a microjet-cooled flange for electronic devices.

FIG. 4 shows an isometric view of the embodiment presented in FIG. 3, with internal fluid cooling features shown with hidden lines.

FIG. 5 shows a cross sectional view of one embodiment of a microjet-cooled flange used as part of a power amplifier package.

FIG. 6 shows an isometric view of one embodiment of a microjet-cooled flange as part of a packaged power amplifier device.

FIG. 7 shows a cross sectional view taken along line 7-7, FIG. 6, of a microjet-cooled flange as part of a packaged power amplifier device, illustrating internal cooling features that allow the cooling of the power amplifier without amplifier direct contact with the coolant fluid.

FIG. 8 shows a bottom view of a microjet-cooled flange as part of a power amplifier assembly, highlighting some fluid routing features.

FIG. 9 shows a cross sectional view of another embodiment of a microjet-cooled flange, where the flange has been included as part of an insulated-gate bipolar transistor (IGBT) package.

FIG. 10 shows an isometric view of one embodiment of a microjet-cooled flange as part of a packaged IBGT device.

FIG. 11 shows a cross sectional view taken along line 11-11, FIG. 10, of a microjet-cooled flange as part of a packaged IGBT device, illustrating the microjet cooling features within the flange that enable high performance cooling in a compact package.

FIG. 12 shows a cross sectional view of another embodiment of a microjet-cooled flange, where the flange has been included as part of a laser diode package.

FIG. 13 shows an isometric view of one embodiment of a microjet-cooled flange as part of a laser diode package, where the flange is integral with the primary package structure of the laser diode.

FIG. 14 shows a cross sectional view taken along line 14-14, FIG. 13, of a microjet-cooled flange that is integral with a laser diode package.

FIG. 15 shows an exploded view of another embodiment of a microjet-cooled flange, formed by a microjet flange in union with the native flange of the electronic component.

FIG. 16 shows a cross sectional view of the microjet-cooled flange formed by a microjet flange in union with the native flange of the electronic component.

FIGS. 17A and 17B show aspects of an embodiment of a microjet-cooled flange where the nozzles are non-uniformly distributed, so as to reduce temperature gradients in the heated surface.

### DETAILED DESCRIPTION

This disclosure describes the use of a flange, for use in electronics packaging, that contains fluid microjets within its interior to produce effective cooling for the electronic device to which it is attached. The disclosure further describes several possible embodiments of the microjet-cooled flange as all, or part, of a package for devices like power amplifiers, IGBTs, or laser diodes. The disclosure adds new functionality (e.g., advanced microjet cooling) that is integrated within a common packaging component (e.g., the flange) without requiring fluid contact with the electronic device.

Many electronic components involve a semiconductor device that is packaged into an assembly for use in larger, system-level assemblies. In the packaging process, many of these semiconductor devices are affixed onto a small plate, or flange. This flange offers many benefits, including mechanical support, conductive cooling, and mounting features. These features are critical for later system integrators.

These flanges are commonly made from small metal plates, with defined dimensions and interface specifications. Metal plates offer stiff support to avoid stress on the semiconductor, conductive paths for thermal cooling of the semiconductor, coefficient of thermal expansion matching with the electronic die, and easily recognizable mounting features in the form of leads, screw holes, or slots.

However, these metal flanges and their conductive cooling paths are becoming insufficient for cooling of advanced electronic devices with high power density. As a result, many systems must attach supplemental, large, metal heat sinks to the device's existing flange. This approach leads to very large implementations, and ultimately limits the power, and performance, of new electronic devices that are produced, packaged, and sold with industry-standard flange architectures.

Microjet cooling is a technique for cooling high-power devices that is characterized by fluid moving through a nozzle to form a small jet of fluid with substantially greater momentum in one direction than another. When this high-momentum fluid impacts a surface, it greatly compresses the thermal boundary layer at that surface, producing very high heat transfer. Microjet cooling technology has been demonstrated to produce heat transfer coefficients in excess of 200,000 W/m²K, more than ten times that of competing approaches (e.g., microchannels 20,000 W/m²K). This allows the fluid to extract heat from power-dense devices, without the need for additional metal heat spreaders. Microjet cooling is further described in US Patent Application Publication 2019/0013258 and International Patent Application Publication WO 2019/018597, the disclosures of which are incorporated herein by reference in their entireties for all purposes.

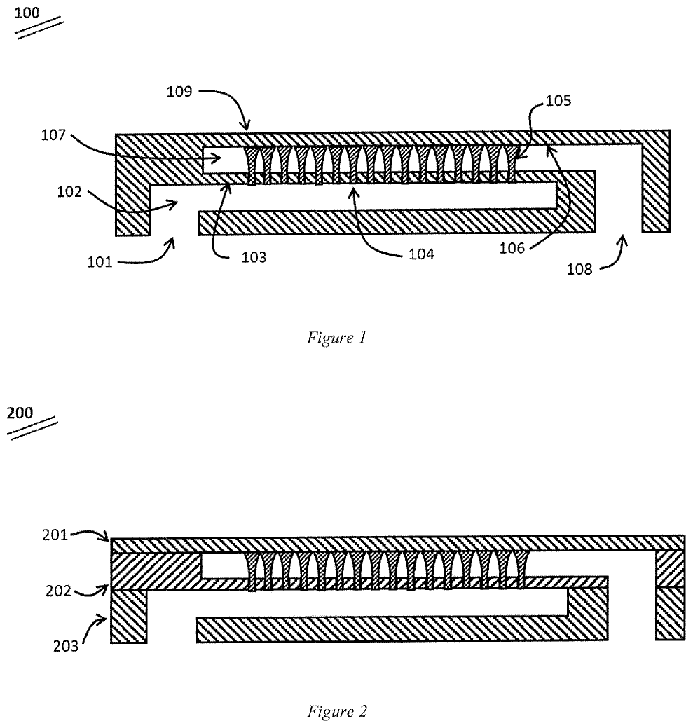

This disclosure describes a microjet-cooled flange for electronics packaging. The flange produces high-performance cooling by using fluid microjets that are contained within the flange. The flange includes one or more fluid inlet, inlet reservoir, microjet nozzle plate, fluid microjet, internal heat transfer surface, exit reservoir, and fluid exit. FIG. 1 illustrates one embodiment of a microjet-cooled flange for electronic device packaging.

FIG. 1 shows one embodiment of a microjet-cooled flange (100). In the flange (100) exists one or more fluid inlet (101). This is where coolant fluid enters the flange. Coolant fluid is supplied from any number of possible external sources of pressurized fluid. The fluid enters the flange and occupies the inlet reservoir (102). Separating the inlet reservoir (102) from the exit reservoir (107) is a microjet nozzle plate (103). The microjet nozzle plate (103) is comprised of one or more nozzles or orifices (104) that produce microjets (105), issuing from the higher-pressure inlet reservoir (102) toward the lower pressure side (107).

The microjets (105) formed by the nozzles (104) in the microjet nozzle plate (103) are issued with substantial fluid velocity and strike the heat transfer surface (106). Notably, in all embodiments this heat transfer surface (106) is interior to the flange. That is, the microjet fluid does not strike the actual semiconductor surface or any other surface outside the extents of the flange. This decouples the electronic device from the flange, leading to greater interchangeability and compatibility with various device types. The semiconductor or electronic device to be packaged (and cooled) may then be attached to the external mating surface (109).

When the microjets (105) strike the heat transfer surface (106), they transfer heat from the electronic device to the coolant fluid. This fluid then occupies the exit reservoir (107) and eventually exits the flange through one or more exit ports (108).

The above description is not meant to limit the versatility of the flange. Other variations may be realized. For example, there may be only a single microjet or an array of microjets. One or more ports may also be located on the same side of the electronic device. More than one electronic device may also be mounted to a single flange. Other variations, including multiple layers between the microjets and device, for example, may also be realized to similar effect.

The microjet-cooled flange may also be manufactured in different ways, which may influence the design. For example, FIG. 1 illustrates one embodiment where the microjet-cooled flange is of monolithic construction. Such a flange may be realized, for example, through additive manufacturing or 3D printing techniques.

FIG. 2 illustrates an embodiment of a microjet-cooled flange that may be produced by more conventional manufacturing techniques. In this example, three layers have been produced, which may be done separately. The reservoir layer (203) includes fluid routing on the higher pressure (inlet) side of the flange. A microjet nozzle plate layer (202) may be fabricated separately, with orifices for the microjet nozzles. A cover plate layer (201), which then serves as the heat transfer surface, may be the surface to which the electronic device is ultimately mounted. Distinct layers (201, 202, 203) may be bonded to form a single flange (200) by several leak-free means, including adhesives, dip brazing, or soldering. Other techniques are also possible, of course.

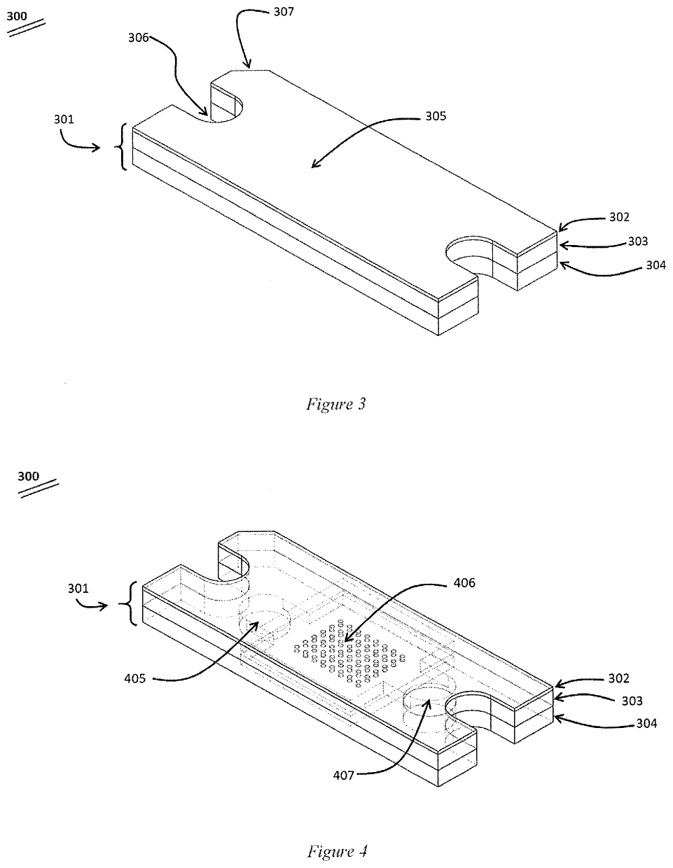

FIG. 3 shows one possible embodiment of the microjet-cooled flange (300). The stackup of layers (301) may be distinct layers or one piece as previously described. For example, three distinct layers (302, 303, 304) are also highlighted. The electronic device may, for example, be disposed on the top mating surface (305) of the flange. Notably, in many embodiments, the microjet-cooled flange (300) does not need to be produced in metal. Less expensive, lower conductivity materials can be used due to the high heat transfer coefficient of microjets. Even for high performance applications, excellent heat transfer may be achieved with only the heat transfer layer (302) being made from high conductivity materials, while other layers (303, 304) can be made from less expensive plastics, for example.

The fluid cooling and routing is contained completely within the microjet-cooled flange. That is, the coolant fluid does not contact the heat generating device directly. Fluid (and cooling) remains within the flange, except for the inlet and exit ports.

The microjet-cooled flange may also include features to allow it to be compatible with many existing packaged devices. For example, the microjet-cooled flange may include holes or slots (306) for attaching the packaged device to a circuit board or other next-level assembly. Also possible are orientation or alignment fiducials (307) for ease of part identification.

FIG. 4 further illustrates the embodiment from FIG. 3, but with transparent surfaces to view the internal geometry of this microjet-cooled flange instantiation. The full flange (300) may be comprised of a single assembly (301) or multiple layers that are attached (302, 303, 304). Within the flange, coolant fluid is taken in through one or more inlet ports (405). Coolant fluid then moves from regions of higher pressure to those of lower pressure, in the course of which the fluid passes through an internal microjet nozzle plate (406) and forms one or more microjets. Exhaust fluid is later expelled through one or more exit ports (407).

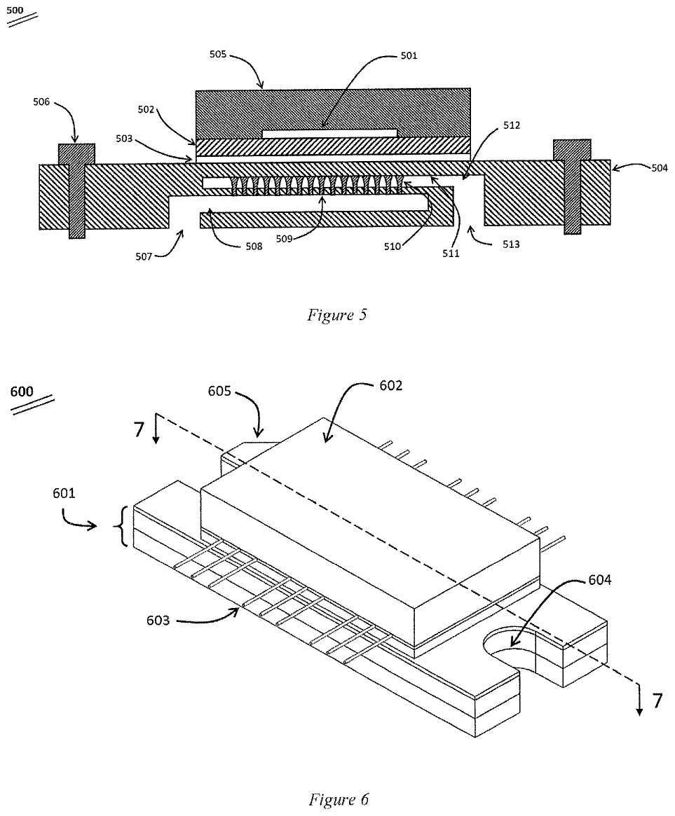

FIG. 5 shows one embodiment of a microjet-cooled flange for power amplifiers. The microjet-cooled flange (504) forms a primary plate for the assembly. Fluid enters the microjet-cooled flange through one or more fluid inlets (507). Fluid then fills the higher-pressure inlet reservoir (508) where it is guided through one or more orifices in the microjet nozzle plate (509). While passing through the nozzles (509), the fluid forms one or more microjets (510) that are directed at the heat transfer surface (511). The heat transfer surface (511) is contained within the microjet-cooled flange. The microjets typically strike perpendicular to the heat transfer surface for greatest effect, but may strike the heat transfer surface at any angle. At the heat transfer surface (511), heat is transferred from the surface to the fluid. After collecting heat from the surface, the fluid traverses the exit reservoir (512) before exiting the microjet-cooled flange through one or more exit ports (513).

On this microjet-cooled flange may be disposed a power amplifier circuit (501). The power amplifier circuit may be a semiconductor device made, for example, from silicon, gallium nitride, silicon carbide, gallium arsenide, diamond, or another material. The power amplifier (501) may be disposed on a substrate (502) for mechanical support and thermal conductivity. The substrate may be, for example, silicon carbide, copper, copper-molybdenum, aluminum, diamond, or another material. Covering the top side of the power amplifier circuit (501) may be a cap (505) that protects the circuit. The cap (505) may be one material or a combination of materials including, for example, plastic, epoxy, solder, or other materials. The power amplifier (and supporting items) may then be attached to the microjet-cooled flange by, for example, solder, epoxy, adhesive, or other thermal interface material (503).

The power amplifier circuit, substrate, package, and interface material are typically designed by the circuit manufacturer to minimize the thermal resistance (and, therefore, temperature rise) of the encapsulated device. This means that there usually exists a strong thermal path from the power amplifier (501) to the lower surface of the interface material (503). With a low-performance thermal management solution for the power amplifier to mount to, however, the temperatures rises can still be significant. The microjet-cooled flange provides a short, direct path from the circuit's primary thermal interface (503) to the heat transfer surface (511) and the coolant fluid. This greatly minimizes the temperature rise of the device, and it occurs within a compact form factor that is already in use in many packaging facilities, and can easily affix to new or existing circuit boards with standard mounting definitions and fasteners (506).

In operation, a single phase fluid is administered. This fluid may be any suitable coolant, including air, water, ethylene glycol, propylene glycol, ethanol, R134A, ammonia, or any other fluid. A combination of two or more of these fluids may also be used. Fluid-tight seals of any type may be formed between layers containing fluid, which may include the use of epoxies, gaskets, soldering, bonding, or any other suitable method. Of course, the construction may not use different layers and may also be a single monolithic part.

The inlet (507) and outlet (513) may be of any type. They may also, for example, provide transmission to/from other components that require cooling. Such other components may be in neighboring parts of the assembly and may require transmission via tubing to other parts of the system. The inlet and outlet may interface with a fitting (e.g. barb, quick disconnect, compression), tubing, a manifold, or any other suitable method of interfacing fluids.

While FIG. 5 shows the microjet-cooled flange in use with a single power amplifier circuit, multiple components may be disposed on a single flange. Each component on the flange may be cooled by a single or multiple microjets within the flange, impinging upon the interior heat transfer surface.

FIG. 6 depicts the microjet-cooled flange with a power amplifier circuit and package disposed on it. The microjet-cooled flange (601) is used as the primary mount and heat sink for the packaged power amplifier (602). The higher performance cooling provided by the microjet-cooled flange over traditional solid metal flanges allows higher power amplifier circuits within the package. The compact form factor of the microjet-cooled flange allows it to be interchangeable with current packaging technologies, including the use of standard leads (603) for mounting to circuits boards, mounting slots (604) for fastening to the next level of assembly, and one or more orientation fiducials (605) for ensuring proper installation in system-level assemblies.

FIG. 7 shows a cutaway cross section view of a power amplifier assembly disposed on a microjet-cooled flange. In this embodiment, a packaged power amplifier circuit (602) has been attached to the top layer (702) of the microjet-cooled flange (601). This attachment (706) may be done by several methods including, for example, solder, epoxy, adhesive, another material, or a combination of these materials.

In all embodiments, the electronic device to be cooled (here, for example, the power amplifier) is mounted to the surface opposite the internal heat transfer surface (710). The material between the mounting surface and the internal heat transfer surface may be any material, but is typically a thermally conductive metal like copper, copper-molybdenum, or aluminum, or another conductive material such as silicon carbide or diamond.

Coolant fluid enters the microjet-cooled flange through one or more inlets (707) and proceeds to flow through the inlet reservoir (713). A microjet nozzle plate (708) separates the inlet reservoir (713) from the exit reservoir (711). The fluid is forced through one or more orifice (709) in the nozzle plate (708), forming one microjet per orifice. It is these microjets that then strike the internal heat transfer surface (710) causing heat to be transferred from the surface to the fluid. Due to the close proximity of the device (705) and the transfer of heat to the fluid (at surface 710), and owing to the high heat transfer coefficients produced by microjets, the heat is effectively dissipated from the component to maintain proper operating temperatures, even with very large power dissipation.

After transferring the heat from the surface to the fluid, the fluid traverses the outlet reservoir (711) and exits the microjet-cooled flange through one or more exit ports (712). These ports may be open ports, or may have other methods of attachment including, for example, tubes, barbed fittings, quick disconnects, push-to-connect fittings, or a separate manifold for fluid conveyance.

The microjet-cooled flange can offer near equally high performance even when non-mounting portions (703, 704) are made from any number of other materials, including low conductivity ones such as plastic. These layers do not substantially participate in the heat transfer.

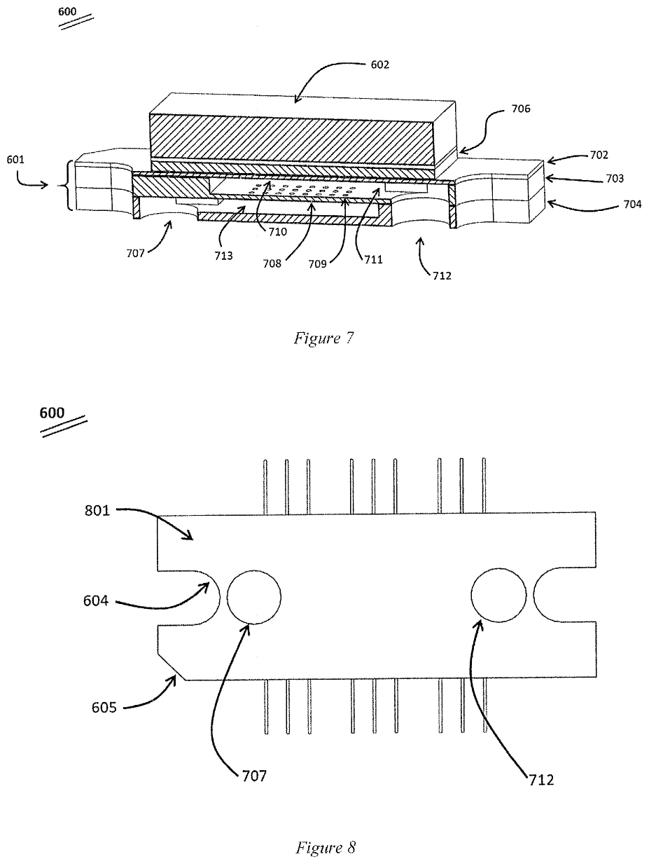

FIG. 8 shows the bottom view of one embodiment of a microjet-cooled flange for power amplifier applications. Here, the lower surface (801) of the flange may be used to attach to a typical assembly such as a printed circuit board or metal mount. This attachment may be done, for example, using fasteners and features like slots (604). An inlet port (707) and exit port (712) may also be disposed on the lower surface for fluid conveyance. Of course, the inlet and outlet ports are not limited to being located on the lower surface and may be located on the top surface or a side surface, for example. Other features on the microjet-cooled flange, such as an orientation fiducial (605), may be present to facilitate proper installation of the component at the next level of system integration.

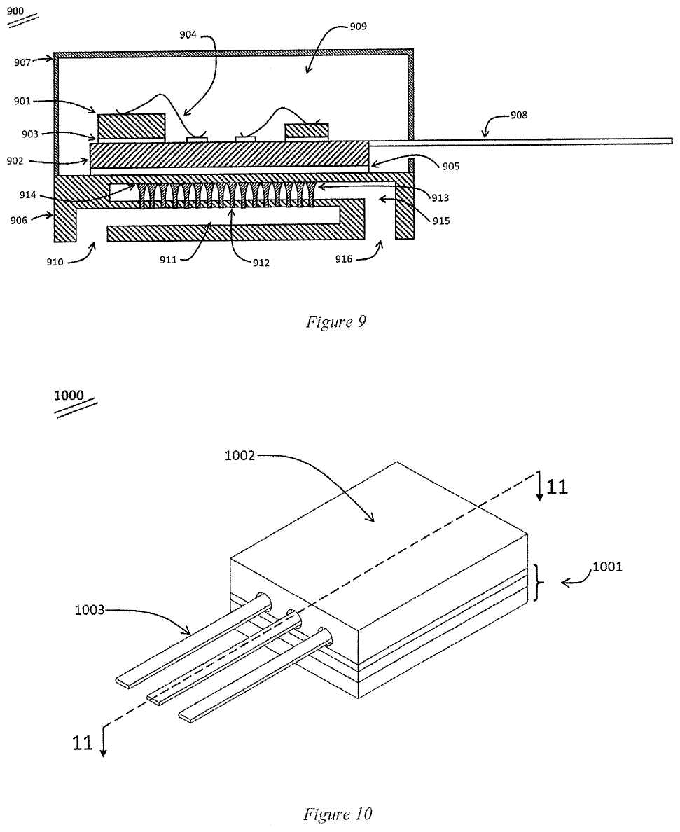

FIG. 9 shows another embodiment (900) of microjet-cooled flanges, for insulated-gate bipolar transistors (IGBT). The microjet-cooled flange (906) forms the primary backing for the assembly/package. Fluid enters the microjet-cooled flange through one or more fluid inlets (910). Fluid then fills the higher-pressure inlet reservoir (911) where it is subsequently guided through one or more orifice in the microjet nozzle plate. This nozzle plate is the separation between the higher-pressure inlet reservoir (911) and the lower pressure exit reservoir (915). While passing through the nozzles (912), the fluid forms one microjet (913) per nozzle that is directed at the heat transfer surface (914). The heat transfer surface (914) is contained within the microjet-cooled flange. The microjets typically strike perpendicular to the heat transfer surface for greatest effect, but may strike the heat transfer surface at any angle. At the heat transfer surface (914), heat is transferred from the surface to the fluid. After collecting heat from the surface, the fluid enters the exit reservoir (915) before exiting the microjet-cooled flange through one or more exit ports (916).

On this microjet-cooled flange may be disposed an IGBT device. The IGBT may be comprised of a semiconductor device made, for example, from silicon, gallium nitride, silicon carbide, gallium arsenide, diamond, or another material. The IGBT chip or chips (901) may be disposed on a substrate (902) for mechanical support and thermal conductivity. The substrate may be, for example, polyimide, fiberglass, ceramic, alumina, direct bonded copper, or another material. Attachment (903) between the device (901) and the substrate (902) may be done, for example, by solder, epoxy, direct bonded copper, or another method. Individual chip or chips (901) within the IGBT package may be electrically connected to each other or to the substrate by, for example, wire bonds (904).

The chips, substrate, and other components forming the IGBT are attached to the microjet-cooled flange (906). This attachment (905) may be done by a variety of methods, including epoxy, solder, adhesive, or other method. In this embodiment, the microjet-cooled flange serves as the primary thermal path and a structural support for the IGBT package. The IGBT circuitry is typically protected by a cover (907). The cover (907) may be one material or a combination of materials, for example, plastic, epoxy, solder, or other materials. Covers typically include cutout features for electrical pin (908) egress. Any volume (909) between the components and the cover may be left empty or may be filled with a gap filler or epoxy, for example.

The IGBT circuit, substrate, package, and interface material are typically designed by the circuit manufacturer to minimize the thermal resistance (and, therefore, temperature rise) of the encapsulated device. This means that there usually exists a strong thermal path from the IGBT chips (901) to the lower surface of the interface material (905). With a low-performance thermal management solution for the IGBT to mount to, however, temperature rises can be significant. The microjet-cooled flange provides a short, direct path from the circuit's primary thermal interface (905) to the heat transfer surface (914) and the coolant fluid. This greatly minimizes the temperature rise of the device, and it occurs within a compact form factor that is already in use in many packaging facilities and can easily affix to new or existing assemblies.

In operation, a single phase fluid is administered. This fluid may be any suitable coolant, including air, water, ethylene glycol, propylene glycol, ethanol, R134A, ammonia, or any other fluid. A combination of two or more of these fluids may also be used. Fluid-tight seals of any type may be formed between layers containing fluid, which may include the use of epoxies, gaskets, soldering, bonding, or any other suitable method. Of course, the construction may not use different layers and may also be a single monolithic part.

The inlet (910) and outlet (916) may be of any type. They may also, for example, provide transmission to/from other components that require cooling. Such other components may be in neighboring parts of the assembly and may require transmission via tubing to other parts of the system. The inlet and outlet may interface with a fitting (e.g. barb, quick disconnect, compression), tubing, a manifold, or any other suitable method of interfacing fluids.

FIG. 10 depicts the microjet-cooled flange as part of a packaged IGBT device (1000). The microjet-cooled flange (1001) is used as the primary package backing and heat sink for the IGBT (1002). The high-performance cooling provided by the microjet-cooled flange over traditional solid metal plates allows higher power IGBTs within the same or similar package. The compact form factor of the microjet-cooled flange allows it to be interchangeable with current packaging technologies, including the use of standard leads (1003) for mounting to circuits boards. While the microjet-cooled flange (1001) is shown here as comprised of three layers, it may be formed by any number of layers including a single monolithic layer.

FIG. 11 illustrates a cross section of one embodiment of an assembly (1000) comprising an IGBT disposed on a microjet-cooled flange (1001). One or more IGBT chips (1101) are disposed on a substrate (1102), which is disposed on the microjet-cooled flange (1001) by some method of heat-conductive bonding (1103). This bonding may be, for example, direct bonded copper, solder, epoxy, adhesive, or another material. A cover (1105) encapsulates the electronic components of the IGBT package, with features for electrical leads (1003) to extend from the package.

Heat generated by the IGBT is conducted through any package layers, including the substrate (1102) and attachment (1103) to reach the top exterior surface of the microjet-cooled flange. This heat is then conducted through a short distance (e.g., the thickness may be about 500 μm. Other thicknesses are possible) to the internal heat transfer surface (1109) of the microjet-cooled flange.

Coolant fluid enters the microjet-cooled flange through one or more inlet ports (not shown) and into the higher-pressure inlet reservoir (1107). The coolant is then driven through one or more orifices (1108) in the microjet nozzle plate that separates the higher-pressure reservoir (1107) and the lower-pressure reservoir (1110). As it passes through each nozzle (1108), the fluid forms a microjet that is directed at, and later strikes, the internal heat transfer surface (1109). This leads to effective transfer of the heat between the internal heat transfer surface and the fluid, ultimately cooling the IGBT device.

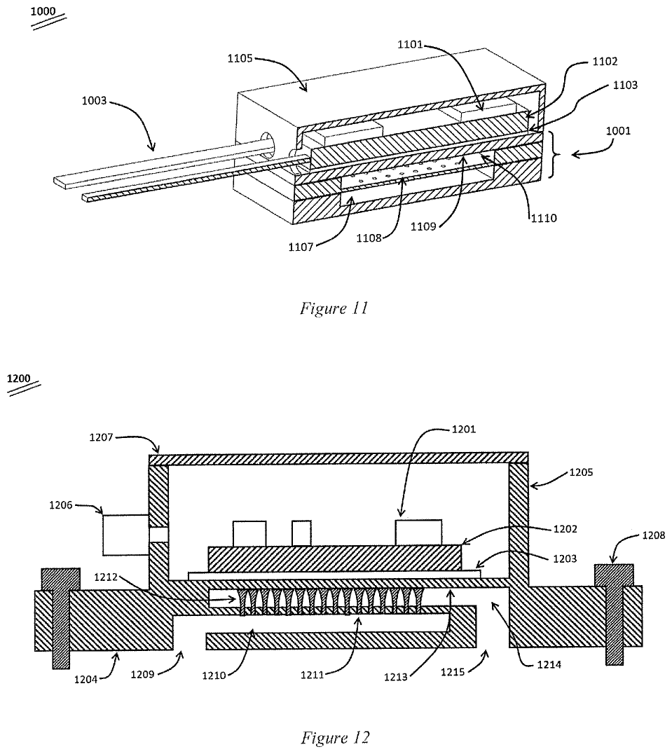

FIG. 12 shows another embodiment of microjet-cooled flanges for laser diode packages. The microjet-cooled flange (1204) forms the primary package for the assembly (1200). Fluid enters the microjet-cooled flange through one or more fluid inlets (1209). Fluid then fills the higher-pressure inlet reservoir (1210) where it is subsequently guided through one or more orifices in the microjet nozzle plate. This nozzle plate is the separation between the higher-pressure inlet reservoir (1210) and the lower pressure exit reservoir (1214). While passing through the nozzles (1211), the fluid forms one microjet (1212) per nozzle that is directed at the heat transfer surface (1213). The heat transfer surface (1213) is contained within the microjet-cooled flange. The microjets typically strike perpendicular to the heat transfer surface for greatest effect, but may strike the heat transfer surface at any angle. At the heat transfer surface (1213), heat is transferred from the surface to the fluid. After collecting heat from the surface, the fluid fills the exit reservoir (1214) before exiting the microjet-cooled flange through one or more exit ports (1215).

On this microjet-cooled flange may be disposed a laser diode package. The laser diode may be comprised of some combination of semiconductor laser diode chips (1201), base plate (1202), and other components which may include, for example, optical components and fiber couplings. The laser diode components (1201) may be disposed on a base plate (1202) for mechanical support and thermal conductivity. The substrate may be, for example, aluminum, copper, ceramic, or another material. Attachment between the devices (1201) and the base plate (1202) may be done, for example, by solder, epoxy, or another method.

The chips, substrate, and other components forming the laser diode are attached to the microjet-cooled flange (1204). This attachment (1203) may be done by a variety of methods, including epoxy, solder, adhesive, or other material. In this embodiment, the microjet-cooled flange serves as the primary thermal path and a structural package for the laser diode. The package is typically protected by a lid (1207). The lid (1207) may be, for example, plastic, aluminum, or another material.

In some embodiments, other portions of the package including, for example, the side walls (1205) may be integrated with the microjet-cooled flange (1204). These side walls may form a continuous perimeter around the laser diode components or may have cutouts for inlet/egress from the package, for example cutouts for electrical leads, optical fiber, or an optical window (1206).

The laser diode, base plate, package, and interface material are typically designed by the system integrator to minimize the thermal resistance (and, therefore, temperature rise) of the packaged device. This means that there usually exists a strong thermal path from the diode chips (1201) to the lower surface of the interface material (1203). With a low-performance thermal management solution for the diode to mount to, however, the temperatures rise can be significant which may cause reduced performance, such as undesirable wavelength shifts. The microjet-cooled flange provides a short, direct path from the circuit's primary thermal interface (1203) to the heat transfer surface (1213) and the coolant fluid. This minimizes the temperature rise of the device. Such a microjet-cooled flange for laser diodes can be designed for interchangeability at the system level by consideration of fastener compatibility (1208) with current mounting techniques.

In operation, a single phase fluid is administered. This fluid may be any suitable coolant, including air, water, ethylene glycol, propylene glycol, ethanol, R134A, ammonia, or any other fluid. A combination of two or more of these fluids may also be used. Fluid-tight seals of any type may be formed between layers containing fluid, which may include the use of epoxies, gaskets, soldering, bonding, or any other suitable method. Of course, the construction may not use different layers and may also be a single monolithic part.

The inlet (1209) and outlet (1215) may be of any type. They may also, for example, provide transmission to/from other components that require cooling. Such other components may be in neighboring parts of the assembly and may require transmission via tubing to other parts of the system. The inlet and outlet may interface with a fitting (e.g. barb, quick disconnect, compression), tubing, a manifold, or any other suitable method of interfacing fluids.

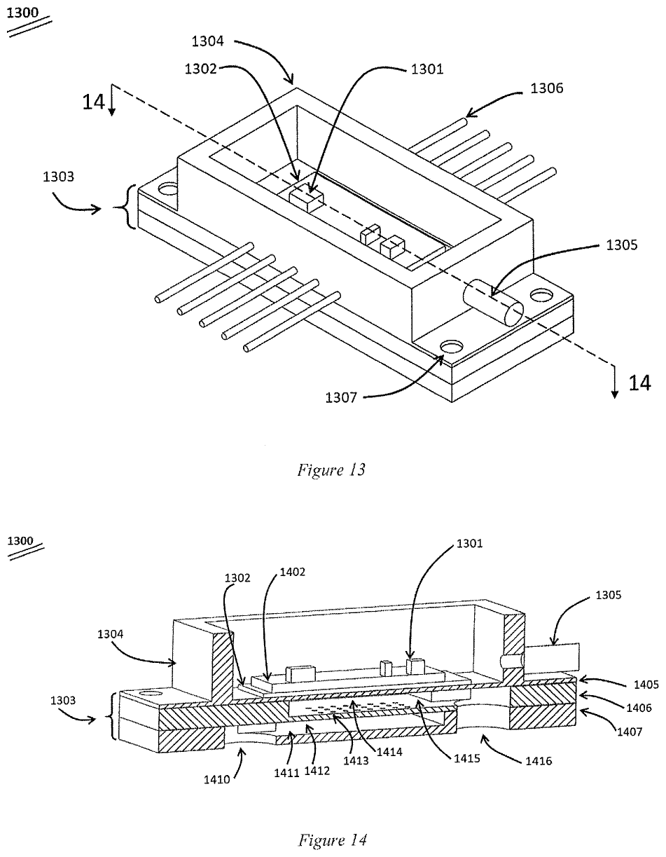

FIG. 13 depicts the microjet-cooled flange forming a laser diode package (1300). The microjet-cooled flange (1303) is used as the primary packaging and heat sink for the laser diodes (1301) and any other internal components including, for example, thermo-electric coolers (1302). The microjet-cooled flange may be integral with the walls (1304) of the package. The high-performance cooling provided by the microjet-cooled flange over traditional solid metal plates allows higher power laser diodes to be included within the same or similar package. The microjet-cooled flange also allows the incorporation of common laser diode features, such as standard leads (1306), optical fiber couplings (1305), and fastener mounting features (1307). While the microjet-cooled flange (1303) is shown here as comprised of three layers, it may be formed by any number of layers including a single monolithic layer. The walls (1304) may be an integral part with the microjet-cooled flange (1303) or they may be separately attached.

FIG. 14 is a cross sectional view of an assembly (1300) comprising a laser diode disposed on a microjet-cooled flange. In this embodiment, laser diodes (1301) and other laser diode components are disposed on a base plate (1402). The electrical and optical components along with the base plate may also be disposed on a thermo-electric cooler (1302), then attached to the microjet-cooled flange (1303).

The microjet-cooled flange (1303) may be comprised of a single layer, or as distinct layers (1405, 1406, 1407) that are then attached via any leak-free method. The microjet-cooled flange may also be integrated with perimeter walls (1304) that surround the sides of the electrical and optical components, forming much of the laser diode package. These walls (1304) may also include cutouts which may, for example, be used for optical windows or fiber couplings (1305).

Coolant fluid enters the microjet-cooled flange through one or more inlet ports (1410) and occupies the higher-pressure inlet reservoir (1411). This higher-pressure inlet reservoir (1411) is separated from the lower-pressure outlet reservoir (1415) by a microjet nozzle plate (1412). Disposed within this nozzle plate are one or more orifices (1413). As fluid passes through each orifice, a microjet is formed. The microjets are directed toward, and strike, the internal heat transfer surface (1414). At this surface, the heat is transferred from the conductive package to the coolant fluid. The fluid then traverses the outlet reservoir (1415) and exits out one or more exit ports (1416).

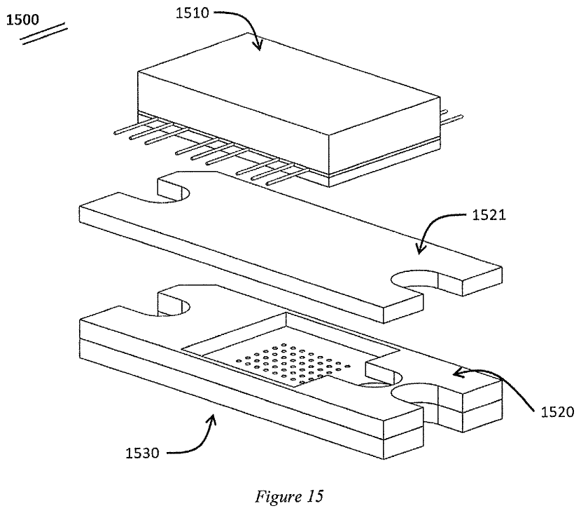

In yet another embodiment, a microjet flange can be configured to be compatible with the native flange commonly sold in electronics packages to form a microjet-cooled flange. FIG. 15 shows an exploded deconstructed view (1500) of the microjet-cooled flange formed by union of a microjet flange and a native device flange. Microjet-cooled flange (1530) is composed of a microjet flange (1520) and native flange (1521), which together form a full sealed flange in which fluid passes. Note that in this case, the electronic heat generating device (1510) often will not be disposed on the native flange (1521) before attachment to microjet flange (1520) to form microjet-cooled flange (1530). For example, the electronics packaging sequence may involve first attaching native flange (1521) to microjet flange (1520), forming microjet-cooled flange (1530), and further attaching electronic device (1510) to the microjet-cooled flange (1530). This differs from the normal processing, where the device (1510) is connected directly to the native flange (1521), with cooling and system integration occurring thereafter.

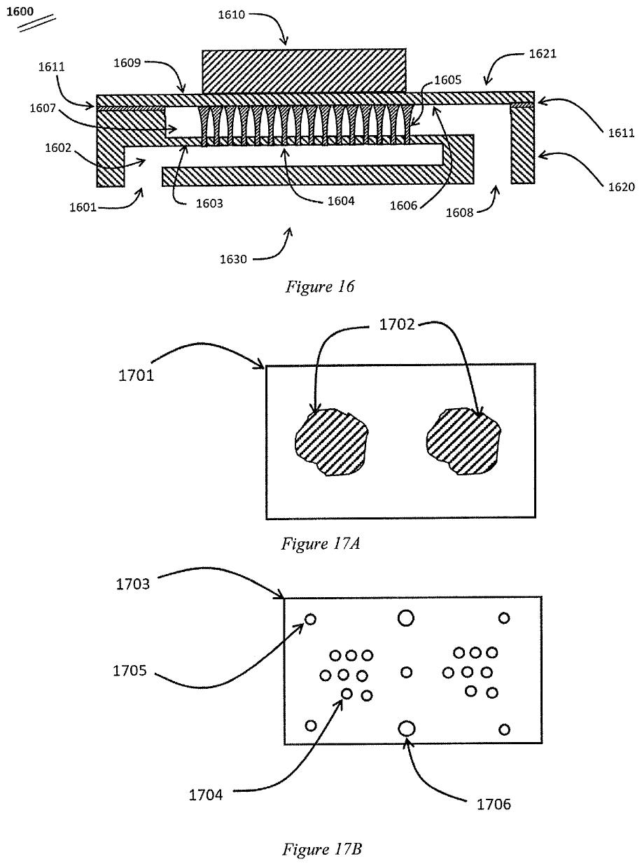

FIG. 16 shows a cross sectional view (1600), where the microjet flange (1620) creates a union with the native device flange (1621) via attachment mechanism (1611) to form a microjet-cooled flange (1630). In the microjet-cooled flange (1630) exists one or more fluid inlet (1601). This is where coolant fluid enters the flange. Coolant fluid is supplied from any number of possible external sources of pressurized fluid. The fluid enters the flange and occupies the inlet reservoir (1602). Separating the inlet reservoir (1602) from the exit reservoir (1607) is a microjet nozzle plate (1603). The microjet nozzle plate (1603) is comprised of one or more nozzles or orifices (1604) that produce microjets (1605), issuing from the higher-pressure inlet reservoir (1602) toward the lower pressure side (1607).

The microjets (1605) formed by the nozzles (1604) in the microjet nozzle plate (1603) are issued with substantial fluid velocity and strike the heat transfer surface (1606). Notably, as in all embodiments, this heat transfer surface (1606) is interior to the flange. That is, the microjet fluid does not strike the actual semiconductor surface or any other surface outside the extents of the flange (1630). The semiconductor or electronic device to be packaged (and cooled) (1610) may then be attached to the external mating surface (1609).

When the microjets (1605) strike the heat transfer surface (1606), they transfer heat from the electronic device to the coolant fluid. This fluid then occupies the exit reservoir (1607) and eventually exits the flange through one or more exit ports (1608).

In all embodiments, the nozzles may be disposed in arrays so as to provide cooling for electronic devices of a range of different sizes. Such devices may contain length scales that range from 5-50 mm, for example. Therefore, the size, location, and distribution of nozzles are carefully chosen to provide adequate cooling of the entire device. The nozzles may be disposed in linear arrays, circular arrays, or any other pattern that serves to help cover the surface of the heat-generating devices. The nozzles may be far apart or close together, details of which are carefully chosen in balancing thermofluidic considerations such as, for example, heat transfer and pressure drop.

In certain electronic devices, the heat may not be generated uniformly across the device surface to be cooled. Such sections of the surface where more heat is being generated are therefore more prone to increases in temperature, sometimes referred to as “hot spots”. In these cases, it may be advantageous to concentrate nozzles nearer to the hot spots of higher heat generation, while having more sparsity in the array where there is lower or no heat generation. This allows for improved cooling efficiency, as better cooling occurs using the same amount of fluid flow, compared to a case where nozzles are uniformly disposed on the nozzle plate.

In addition to the distribution of nozzles, the size and shape of each individual nozzle may vary across the array to balance tradeoffs of, for example, pressure, flow rate, and heat transfer, with the heat generating character of the electronic device. For example, a set of jets with lower heat transfer capability may be administered around areas of low heat generation, while jets with high heat transfer capability may be administered near hot spots.

FIGS. 17A and 17B illustrate one possible implementation for matching hot spots on the device with the microjet-cooled flange. The heat generating device (1701) may have one or more areas (1702) within it that are higher heat dissipation than the rest of the device. The microjet-cooled flange nozzle plate (1703) may have an array of nozzles for cooling the device (1701). It may be beneficial to have a non-uniform distribution of nozzles, where nozzles may be arranged in a non-uniform way (1704) to provide better cooling to device hot spots (1702). In other areas, nozzle distribution may, for example, be more sparse (1705) where there is lower heat load, or they may be shaped or sized differently (1706). These non-uniform arrangements may produce more uniform temperatures on the device.

As part of this disclosure, electronics flanges (as used on many electronics packages including power amplifiers, IGBTs, and laser diodes) are constructed with internal fluid routing, an internal microjet nozzle plate, and an internal heat transfer surface to bring high-performance cooling within the package. This approach brings active microjet cooling within the device flange, but without direct contact between the coolant fluid and the device. This approach greatly reduces the thermal path for heat generated by the device, in a sealed subassembly with defined inlet/exit ports. The microjet-cooled flanges are designed to take the place of commonly available solid metal flanges.

In one embodiment, the present disclosure discloses a method of cooling a semiconductor device by using the device flange. First, the device or its carrier is disposed onto the mating surface of the microjet-cooled flange. Within this microjet-cooled flange, coolant fluid enters and fills a high-pressure reservoir. An internal microjet nozzle plate separates this high-pressure reservoir from a low-pressure reservoir. The coolant fluid is then driven through one or more orifice in this nozzle plate, forming one microjet per nozzle. The microjets issue into the low-pressure reservoir, striking the internal heat transfer surface of the flange. The device (or carrier) is mounted to the opposite (exterior) surface of the internal heat transfer surface. Heat is transferred from the device, through a short flange thickness, and into the coolant fluid. The fluid then exits the microjet-cooled flange, taking the waste heat with it.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A flange for cooling an electronic component, comprising:
a heat transfer portion with an inner surface, and an opposed outer surface that is configured to be thermally coupled to the electronic component;
a high-pressure fluid reservoir;
a fluid inlet in fluid communication with the high-pressure reservoir, the inlet configured to conduct single-phase cooling fluid into the flange;
a low-pressure fluid reservoir that is in fluid communication with the inner surface of the heat transfer portion;
a fluid outlet in fluid communication with the low-pressure reservoir, the outlet configured to conduct the fluid out of the flange; and
a plurality of fluid nozzles that are each configured to transmit the fluid from the high pressure reservoir to the low pressure reservoir in the form of jets that are configured to strike the inner surface of the heat transfer portion.

2. The flange of claim 1, wherein a perimeter can be drawn around the plurality of fluid nozzles without encompassing the fluid outlet.

3. The flange of claim 1, wherein the fluid nozzles are configured non-uniformly relative to the heat transfer portion, to provide more effective cooling to certain areas for reduction of temperature gradients across the electronic component.

4. The flange of claim 1, wherein the flange is of unitary structure.

5. The flange of claim 4, wherein the flange is fabricated using additive manufacturing.

6. The flange of claim 1, wherein the plurality of fluid nozzles form microjet nozzles.

7. The flange of claim 6, where the microjet nozzles serve to form jets that are configured to strike substantially perpendicularly to the inner surface of the heat transfer portion, to create fluid flow with substantially high momentum in said perpendicular direction.

8. The flange of claim 1, configured to serve as an electronics base plate.

9. The flange of claim 1, wherein the flange is fabricated from at least two distinct members that are joined together.

10. The flange of claim 9, wherein a first member comprises the heat transfer portion that is made from a material with high heat conductivity.

11. The flange of claim 10, wherein a second member is made from a material with lower heat conductivity than that of the first member.

12. The flange of claim 1, further comprising at least one hole or slot that is configured to attach the flange to another structure.

13. The flange of claim 1, wherein the heat transfer portion is configured to provide a short, direct path from a primary thermal interface of the electronics component to the inner surface of the heat transfer portion.

14. The flange of claim 1, wherein the fluid nozzles comprise orifices through a thickness of an internal microjet nozzle plate of the flange.

15. The flange of claim 1, wherein the electronic component comprises at least one transistor.

16. The flange of claim 1, wherein the electronic component comprises at least one laser diode.

17. A flange that is configured to serve as a base plate for and to cool an electronic component, comprising:
a heat transfer portion with an inner surface, and an opposed outer surface that is configured to be thermally coupled to the electronic component, wherein the heat transfer portion is configured to provide a short, direct path from a primary thermal interface of the electronics component to the inner surface of the heat transfer portion;
a high-pressure fluid reservoir;
a fluid inlet in fluid communication with the high-pressure reservoir, the inlet configured to conduct single-phase cooling fluid into the flange;
a low-pressure fluid reservoir that is in fluid communication with the inner surface of the heat transfer portion;
a fluid outlet in fluid communication with the low-pressure reservoir, the outlet configured to conduct the fluid out of the flange; and
a plurality of fluid microjet nozzles that are each configured to transmit the fluid from the high pressure reservoir to the low pressure reservoir in the form of jets that are configured to strike the inner surface of the heat transfer portion.

18. The flange of claim 17, wherein the flange is fabricated from at least two distinct members that are bonded together, wherein a first member comprises the heat transfer portion that is made from a material with high heat conductivity.

19. The flange of claim 18, wherein a second member is made from a material with lower heat conductivity than that of the first member.

20. The flange of claim 17, wherein the fluid microjet nozzles comprises orifices through a thickness of an internal microjet nozzle plate of the flange.
